(19) United States
(12) Patent Application Publication
(10) Pub. No.: US 2025/0209233 A1
(43) Pub. Date: Jun. 26, 2025

(54) DATA SYNTHESIZER

(71) Applicant: Booz Allen Hamilton Inc., McLean, VA (US)

(72) Inventors: Ria Leilani Ramirez BALDEVIA, Columbia, MD (US); John O'Neil CASWELL, Columbia, MD (US)

(73) Assignee: Booz Allen Hamilton Inc., McLean, VA (US)

(21) Appl. No.: 18/390,099

(22) Filed: Dec. 20, 2023

(51) Int. Cl. G06F 30/20

(52) U.S. Cl. CPC G06F 30/20

(57) ABSTRACT

Embodiments can relate to a system for generating a simulated dataset related to network activity. The system can include a processor and a memory including a data receiver module and a data synthesizer module. The memory can include instructions stored thereon that when executed by the processor will cause the processor to: execute the data receiver module to receive data including time ordered data and non-time ordered data; execute the data synthesizer module by implementing one or more machine learning models to generate synthetic data from received data. The one or more machine learning models can include a trained dataset trained with time ordered data and non-time ordered data. The data synthesizer can be configured to iteratively update the synthetic data until the synthetic data meets a threshold representative of network activity.

### FIELD

Embodiments relate to systems and methods for generating a simulated dataset related to network activity.

### BACKGROUND INFORMATION

Known systems and methods for data synthesizing suffer from inefficiencies and a lack of functionality. For instance, they tend to be limited to techniques that require selection and extraction of data packets based on time ordered data (e.g., data ordered by time-AKA “time period data”).

Known systems and methods can be appreciated from CN 112801411 Gao et al., CN 113747480 Xing et al., CN 113747500 Yuan et al., CN 114244456 Wang et al., EP 3,840,292 Arpirez et al., TW 202247631 Bai, U.S. Pat. No. 9,578,046 Baker, U.S. Pat. No. 11,601,354 Malhotra et al., U.S. Pat. No. 11,652,713 Watson et al., US 2019/0147343 Lev et al., US 2020/0359265 Azizi et al., US 2021/0125075 Lee, US 2021/0142180 Smith et al., US 2021/0306873 Mokrushin et al., US 2022/0086174 Helmsen et al., WO 2021/242956 Chang et al., WO 2022/139762 Coşkun et al., Ding, S., Kou, L., & Wu, T. (2023). A GAN-Based Intrusion Detection Model for 5G Enabled Future Metaverse. Mobile Networks and Applications, 1-15, Hughes, B., Bothe, S., Farooq, H., & Imran, A. (2019 February). Generative Adversarial Learning for Machine Learning empowered Self-Organizing 5G Networks. In 2019 international conference on computing, networking and communications (ICNC) (pp. 282-286). IEEE, Mozo, A., Pastor, A., Karamchandani, A., de la Cal, L., Rivera, D., & Moreno, J. I. (2022). Integration of Machine Learning-Based Attack Detectors into Defensive Exercises of a 5G Cyber Range. Applied Sciences, 12 (20), 10349, Ring, M., Schlör, D., Landes, D., & Hotho, A. (2019). Flow-based Network Traffic Generation using Generative Adversarial Networks. Computers & Security, 82, 156-172, Tey, F. J., Wu, T. Y., Wu, Y., & Chen, J. L. (2022). Generative Adversarial Network for Simulation of Load Balancing Optimization in Mobile Networks. Journal of Internet Technology, 23 (2), 297-304, Wang, Z., Wang, P., Zhou, X., Li, S., & Zhang, M. (2019 December). FLOWGAN: Unbalanced network encrypted traffic identification method based on GAN. In 2019 IEEE Intl Conf on Parallel & Distributed Processing with Applications, Big Data & Cloud Computing, Sustainable Computing & Communications, Social Computing & Networking (ISPA/BDCloud/SocialCom/SustainCom) (pp. 975-983). IEEE, and Yang, Y., Li, Y., Zhang, W., Qin, F., Zhu, P., & Wang, C. X. (2019). Generative-Adversarial-Network-Based Wireless Channel Modeling: Challenges and Opportunities. IEEE Communications Magazine, 57 (3), 22-27.

### SUMMARY

Embodiments can relate to a system for generating a simulated dataset related to network activity. The system can include a processor. The system can include a memory including a data receiver module and a data synthesizer module. The processor can be associated with the memory. The memory can include instructions stored thereon that when executed by the processor will cause the processor to perform any of the functions disclosed herein. The instructions can cause the processor to execute the data receiver module to receive data including time ordered data and non-time ordered data. The instructions can cause the processor to execute the data synthesizer module by implementing one or more machine learning models to generate synthetic data from received data. The one or more machine learning models can include a trained dataset trained with time ordered data and non-time ordered data. The data synthesizer can be configured to iteratively update the synthetic data until the synthetic data meets a threshold representative of network activity.

Embodiments can relate to a non-transitory machine-readable medium having instructions stored thereon which when executed cause a processor to perform operations. The operations can include executing a data receiver module to receive data including time ordered data and non-time ordered data. The operations can include execute a data synthesizer module by implementing one or more machine learning models to generate synthetic data from received data. The one or more machine learning models can include a trained dataset trained with time ordered data and non-time ordered data. The data synthesizer module can iteratively update the synthetic data until the synthetic data meets a threshold representative of network activity.

Embodiments can relate to a method for generating a simulated dataset related to network activity. The method can involve executing a data receiver operation to receive data including time ordered data and non-time ordered data. The method can involve executing a data synthesizer operation by implementing one or more machine learning models to generate synthetic data from received data. The one or more machine learning models can include a trained dataset trained with time ordered data and non-time ordered data. The data synthesizer operation can iteratively update the synthetic data until the synthetic data meets a threshold representative of network activity.

### BRIEF DESCRIPTION OF THE DRAWINGS

Other features and advantages of the present disclosure will become more apparent upon reading the following detailed description in conjunction with the accompanying drawings, wherein like elements are designated by like numerals, and wherein:

FIG. 1 shows an exemplary system that can be used for generating a simulated dataset; and

FIG. 2 show an exemplary data flow diagram for an embodiment of a synthetic data generator.

### DETAILED DESCRIPTION

Embodiments can relate to a system 100 for generating a simulated dataset related to network activity. The system 100 can generate synthetic data that simulates a given dataset. The simulated dataset can provide a “ground truth”, which can be very useful in developing, training, and/or evaluating machine learning models. For instance, the ground truth data can be artificially generated data defined by the synthetic data that can be configured to maintain certain data properties of the original dataset but omit other superfluous or unnecessary properties. As a non-limiting example, the synthetic data can simulate a dataset pertaining to a network activity of interest (e.g., a cell phone downloading a software application, an attempt to log-in to a secure application, etc.). This simulated data can be used as a ground truth to develop, train, and/or evaluate a model for detecting such activity over a network 102.

The system 100 can receive network data (e.g., a communication or signal) and extract data packets therefrom, which can be used to perform data synthesis on the data. Data extraction can include one or more extract, transform, load (“ETL”) techniques, for example. The ETL technique can be implemented via ETL software, for example. Data extraction can be performed manually, automatically, or a combination of both. Which data packets to select, how many data packets to use, type of extraction, frequency of extraction, etc. can determined by subject matter experts operating the system/method. Conventional systems select and extract data packets based on time ordered data (e.g., data ordered by time—AKA “time period data”). As will be explained herein, the selection and extraction of data packets with embodiments of the system 100, however, can be irrespective of time period data (e.g., the data does not have to be time ordered), and thus the system 100 is not limited in this regard. In addition, the selection and extraction of data packets with embodiments of the system 100 can be focused on certain parts of the data so as to address issues related to homogeneous and heterogeneous data within the received network data.

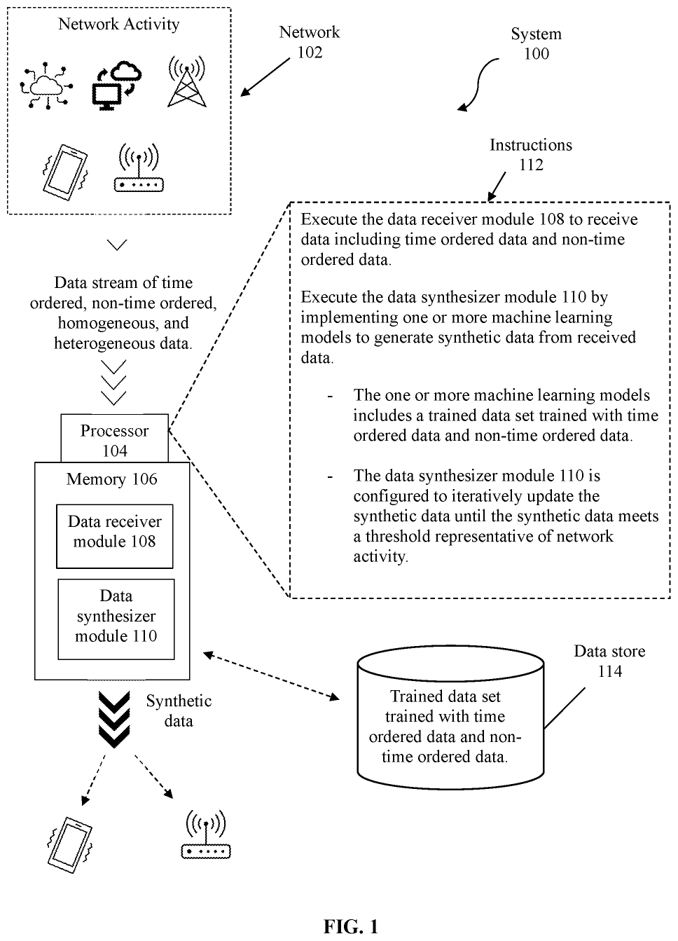

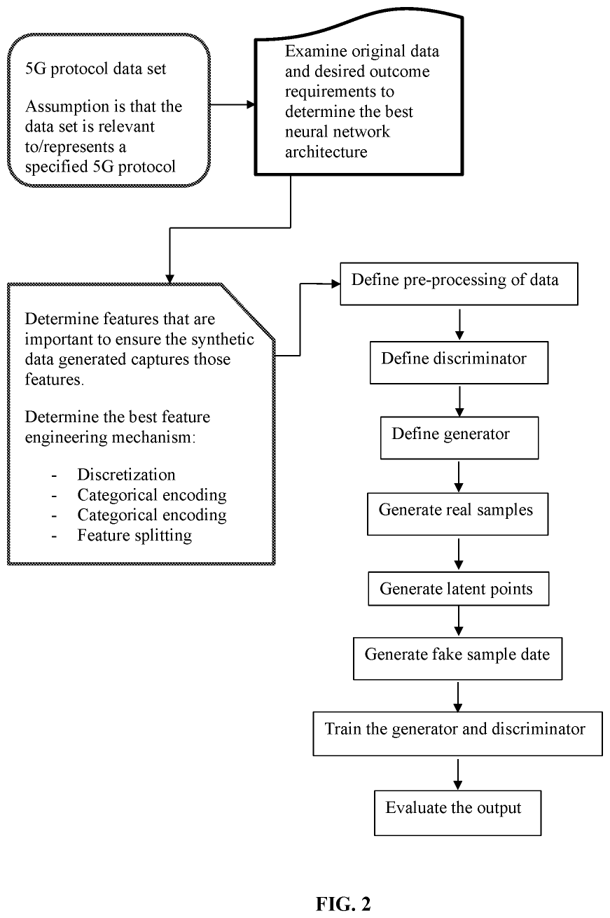

Referring to FIGS. 1 and 2, embodiments of the system 100 can include one or more processors 104. The system 100 can include one or more memories 106. The memory 106 can include one or more data receiver modules 108 and one or more data synthesizer modules 110, the functions of which will be explained in detail later. The processor 104 can be associated with the memory 106, and the memory 106 can include instructions 112 stored thereon that when executed by the processor 104 will cause the processor 104 to perform one or more of the functions disclosed herein.

Any of the processors disclosed herein can be part of or in communication with a machine (e.g., a computer device, a logic device, a circuit, an operating module (hardware, software, and/or firmware), etc.). The processor can be hardware (e.g., processor, integrated circuit, central processing unit, microprocessor, core processor, computer device, etc.), firmware (e.g., firmware module), software (e.g. software module), etc. configured to perform operations by execution of instructions embodied in computer program code, algorithms, program logic, control, logic, data processing program logic, artificial intelligence programming, machine learning programming, artificial neural network programming, automated reasoning programming, etc. The processor can receive, process, and/or store data.

Any of the processors disclosed herein can be a scalable processor, a parallelizable processor, a multi-thread processing processor, etc. The processor can be a computer in which the processing power is selected as a function of anticipated network traffic (e.g., data flow). The processor can include an integrated circuit or other electronic device (or collection of devices) capable of performing an operation on at least one instruction, which can include a Reduced Instruction Set Core (RISC) processor, a Complex Instruction Set Computer (CISC) microprocessor, a Microcontroller Unit (MCU), a CISC-based Central Processing Unit (CPU), a Digital Signal Processor (DSP), a Graphics Processing Unit (GPU), a Field Programmable Gate Array (FPGA), etc. The hardware of such devices may be integrated onto a single substrate (e.g., silicon “die”), distributed among two or more substrates, etc. Various functional aspects of the processor may be implemented solely as software or firmware associated with the processor.

The processor can include one or more processing or operating modules. A processing or operating module can be a software or firmware operating module configured to implement any of the functions disclosed herein. The processing or operating module can be embodied as software and stored in memory, the memory being operatively associated with the processor. A processing module can be embodied as a web application, a desktop application, a console application, etc. The processor can include or be associated with a computer or machine readable medium. The computer or machine-readable medium can include memory.

Any of the memory discussed herein can be computer readable memory configured to store data. The memory can include a volatile or non-volatile, transitory or non-transitory memory, and be embodied as an in-memory, an active memory, a cloud memory, etc. Examples of memory can include flash memory, Random Access Memory (RAM), Read Only Memory (ROM), Programmable Read only Memory (PROM), Erasable Programmable Read only Memory (EPROM), Electronically Erasable Programmable Read only Memory (EEPROM), FLASH-EPROM, Compact Disc (CD)-ROM, Digital Optical Disc DVD), optical storage, optical medium, a carrier wave, magnetic cassettes, magnetic tape, magnetic disk storage or other magnetic storage devices, or any other medium which can be used to store the desired information and which can accessed by the processor.

The memory can be a non-transitory computer-readable medium. The term “computer-readable medium” (or “machine-readable medium”) as used herein is an extensible term that refers to any medium or any memory, that participates in providing instructions to the processor for execution, or any mechanism for storing or transmitting information in a form readable by a machine (e.g., a computer). Such a medium may store computer-executable instructions to be executed by a processing element and/or control logic, and data which is manipulated by a processing element and/or control logic, and may take many forms, including but not limited to, non-volatile medium, volatile medium, transmission media, etc. The computer or machine readable medium can be configured to store one or more instructions thereon. The instructions can be in the form of algorithms, program logic, etc. that cause the processor to execute any of the functions disclosed herein.

Embodiments of the memory can include a processor module and other circuitry to allow for the transfer of data to and from the memory, which can include to and from other components of a communication system. This transfer can be via hardwire or wireless transmission. The communication system can include transceivers, which can be used in combination with switches, receivers, transmitters, routers, gateways, wave-guides, etc. to facilitate communications via a communication approach or protocol for controlled and coordinated signal transmission and processing to any other component or combination of components of the communication system. The transmission can be via a communication link. The communication link can be electronic-based, optical-based, opto-electronic-based, quantum-based, etc. Communications can be via Bluetooth, near field communications, cellular communications, telemetry communications, Internet communications, etc.

Transmission of data and signals can be via transmission media. Transmission media can include coaxial cables, copper wire, fiber optics, etc. Transmission media can also take the form of acoustic or light waves, such as those generated during radio-wave and infrared data communications, or other form of propagated signals (e.g., carrier waves, digital signals, etc.).

Any of the processors can be in communication with other processors of other devices (e.g., a computer device, a computer system, a laptop computer, a desktop computer, etc.). For instance, the processor of the system 100 can be in communication with a processor of a computer device, the processor of the computer device can be in communication with a processor of a display, etc. Any of the processors can have transceivers or other communication devices/circuitry to facilitate transmission and reception of wireless signals. Any of the processors can include an Application Programming Interface (API) as a software intermediary that allows two or more applications to talk to each other. Use of an API can allow software of one processor to communicate with software of another processor of another device(s).

Any of the data or communication transmissions between two components can be a push operation and/or a pull operation. For instance, data transfer between the processor 104 and the memory 106 can be push operation (e.g., the data can be pushed from the memory) and/or a pull operation (e.g., the processor can pull the data from the memory), data transfer between the system 100 and the computer device can be a push and/or pull operation, etc.

The instructions 112 can cause the processor 104 to execute the data receiver module 108. Execution of the data receiver module 108 cause or allow the processor XX to receive network data (e.g., receive communications or signals from a network 102). As noted herein, the received network data can include time ordered data and/or non-time ordered data.

The instructions 112 can cause the processor 104 to execute the data synthesizer module 110 to generate synthetic data from the received data. This can include implementing one or more machine learning models to generate synthetic data from received data. The one or more machine learning models, a trained dataset for the one or more machine learning models, or both can be stored on the memory 106. In the alternative, the one or more machine learning models, the trained dataset for the one or more machine learning models, or both can be stored on data store 114 (e.g., database) that is in communication with the processor 104.

The data synthesizing operation can include extracting data packets from the received network data. The extraction of data packets need not be based on time ordered data because the one or more machine learning models includes a trained dataset trained with time ordered data and non-time ordered data. For instance, the trained dataset includes one or more datasets representative of one or more network activities, wherein these datasets used by the model(s) are already trained with time ordered and non-time ordered data. Thus, the system 100 can receive and process network data, regardless of it being time ordered or not. Synthesized data can be generated by fitting real data to a known or desired distribution, via use of one or more neural network techniques, via one or more adversarial network techniques, etc. As a non-limiting example, data synthesis can be performed using a Generative Adversarial Network (GAN) model. For instance, an exemplary data synthesis implementation can include use of two neural nets (a discriminator and a generator). The generator can create data (fake data) without ever having access to the real data. This generated data can then be combined with real data. The combined data can then be given to the discriminator, where the discriminator attempts to determine which is real data and which is generated data. Feedback on the discriminator's performance (what it got right and what it got wring) is provided to the discriminator. The two neural nets compete against each other to cause the discriminator and the generator to iteratively become better at their respective performances.

The data synthesizer module 110 can be configured to iteratively update the synthetic data until the synthetic data meets a threshold representative of network activity. With an adversarial network technique, for example, data synthesis can include use of two neural nets, as described above. The two neural nets compete against each other to cause the discriminator and the generator to iteratively become better as their respective performances. The synthetic data is iteratively updated until it meets a predetermined threshold value that is acceptable as being representative of a network activity. As a non-limiting example, the synthetic data is updated until there a 95% confidence level is obtained that the synthetic data is representative of a certain network activity (e.g., cell phone downloading a software application). Once the updated synthetic data meets the threshold, it can be designated as data suitable for simulating that network activity. For instance, after being generated and/or after one or more updates, the synthetic data can be compared to a known dataset, a known data distribution, a known data pattern, etc. that is representative of the network activity. The comparison can determine a percent match, and the threshold can be a 95% match. After a 95% math is attained or surpassed, that iteration of synthetic data can be designated and/or used as a simulated dataset for that network activity. This is just one example, and a person of ordinary skill in the art would understand that other comparisons, thresholds, data statistics, etc. can be used.

As noted above, the threshold representative of network activity can be set based on a statistic. However, to accommodate a mix of heterogenous and heterogeneous data being received, it is contemplated for the threshold to also be based on a predefined homogenous data to heterogeneous data ratio. For instance, the received data can include homogeneous or heterogeneous data so the threshold discussed above can be determined at least in part on a homo:hetero ratio (e.g., it may be OK to use data that has 50% heterogenous data to generate synthetic data representative of a computer logging in to a network, but a 90 homogeneous: 10 heterogeneous ratio may be required to generate synthetic data representative of a cell phone downloading a software application). Thus, the threshold representative of network activity can include a predefined homogenous data to heterogeneous data ratio.

An exemplary implementation can be: 1) the system 100 receives data (time ordered data, non-time ordered data, homogeneous data, heterogeneous data, etc.); 2) the system 100 implements a model to generate synthetic data (e.g., this synthetic data is representative of network activity); and 3) the system 100 implements the model to iteratively update the synthetic data until a threshold is met that is representative of the network activity (e.g., the synthetic data is updated until a threshold is met to ensure that the synthetic data is representative of the network activity); 4) the system 100 can use the updated synthetic data as a simulated dataset.

As noted herein, the data can be time ordered or non-time ordered. Time ordered data can include data that is at least one or more of tagged with a time stamp or encoded with a time stamp. Having data in the trained dataset used by the one or more machine learning models trained with time ordered data (e.g., tagged with a time stamp or encoded with a time stamp) and non-time ordered data allows the system 100 to effectively and efficiently process received network data for data synthesis. Conventional systems have to pre-process the data to segment the data into time ordered data and non-time ordered data (thereby requiring additional processing, computational resources, slower processing speeds, etc.), or are only able to receive and process time-ordered data (thereby limiting functionality).

It is contemplated for the network 102 to be a communications network, such as a Personal Area Network, Local Area Network, Wide Area Network, etc. The network activity can be one or more of an action (e.g., a device logging in), an event (e.g., an interruption experienced by a device), or an operation (e.g., a device downloading a software application) within a network associated with received data. Examples can be computer logging in to a network, a cell phone downloading a software application, unauthorized access to the network, detection of a network attack vector, detection of a network interruption, a transfer of a certain type of file, an activity related to a protocol (e.g., a 5G communication protocol) etc.

The processor 104 can execute the data receiver module 108 to receive data from one or more of a live data stream of a network, a memory, a processor, or a communication system. For instance, the received network data can be received and processed in real-time as the network data is generated (e.g., the processor 104 can be a node within the network 102). The received network data can be stored on a memory and received from that memory at a later time. The received network data can be first sent to a processor for processing before being received by the data receiver module 108. The received network data can be received (e.g., intercepted or interrogated) from a communication exchange occurring within a communication system (between two nodes of a network 102).

The data synthesizer module 110 can be configured to iteratively and/or recursively implement the one or more machine learning models to iteratively update the synthetic data. For instance, the data synthesizer module 110 can not only loop through the model to achieve an update iteration, but it can loop a function within the model as part of the update iteration. The function can be looped one or more times to achieve an update iteration.

The one or more machine learning models can include a first machine learning model and a second machine learning model. The data synthesizer module 110 can be configured to implement the first machine learning model to iteratively update the synthetic data until the synthetic data meets a first threshold representative of a first network activity. The data synthesizer module 110 can be configured to implement the second machine learning model to iteratively update the synthetic data until the synthetic data meets a second threshold representative of a second network activity. The system 100 can generate synthetic data for any number of network activities from the same received data (e.g., generate a first synthetic dataset representative of the first network activity, generate a second synthetic dataset representative of the second network activity, etc.), generate a single synthetic dataset that is a combination or amalgamation of two related network activities (e.g., generate a synthetic dataset that is representative of a device being logged into a software application and experiencing an interruption), generate a single synthetic data that is a compilation of network activities (e.g., generate a synthetic dataset that is representative of a device transferring certain type of information to a node and the node thereafter pulling files from the device), etc.

In some embodiment, the instructions 112 can cause the processor 104 to use the synthetic data as a simulated dataset. It is contemplated for the simulated dataset to be used to develop, train, or evaluate a machine learning model.

Exemplary embodiments can relate to a non-transitory machine-readable medium having instructions 112 stored thereon which when executed cause a processor 104 to perform operations. The instructions 112 can cause the processor 104 to execute a data receiver module 108 to receive data including time ordered data and non-time ordered data. The instructions 112 can cause the processor 104 to execute a data synthesizer module 110 by implementing one or more machine learning models to generate synthetic data from received data. The one or more machine learning models can include a trained dataset trained with time ordered data and non-time ordered data. The data synthesizer module 110 can iteratively update the synthetic data until the synthetic data meets a threshold representative of network activity.

The threshold representative of network activity can include a predefined homogenous data to heterogeneous data ratio.

Time ordered data can include data that is at least one or more of tagged with a time stamp or encoded with a time stamp.

Network activity can include at least one or more of an action, an event, or an operation within a network associated with received data.

Receiving data can include receiving data from at least one or more of a live data stream of a network, a memory, a processor, or a communication system.

The data synthesizer module can iteratively or recursively implement the one or more machine learning models to iteratively update the synthetic data.

Exemplary embodiments can relate to a method for generating a simulated dataset related to network activity. The method can involve executing a data receiver operation to receive data including time ordered data and non-time ordered data. The method can involve executing a data synthesizer operation by implementing one or more machine learning models to generate synthetic data from received data. The one or more machine learning models can include a trained dataset trained with time ordered data and non-time ordered data. The data synthesizer operation can iteratively update the synthetic data until the synthetic data meets a threshold representative of network activity.

The threshold representative of network activity can include a predefined homogenous data to heterogeneous data ratio.

The time ordered data can include data that is at least one or more of tagged with a time stamp or encoded with a time stamp.

The network activity can include at least one or more of an action, an event, or an operation within a network associated with received data.

Receiving data can includes receiving data from at least one or more of a live data stream of a network, a memory, a processor, or a communication system.

The method can involve iteratively or recursively implementing the one or more machine learning models to iteratively update the synthetic data.

It will be understood that modifications to the embodiments disclosed herein can be made to meet a particular set of design criteria. For instance, any of the components, features, or steps of apparatuses, systems, or methods disclosed herein can be any suitable number or type of each to meet a particular objective. Therefore, while certain exemplary embodiments of the systems and methods disclosed herein have been discussed and illustrated, it is to be distinctly understood that the invention is not limited thereto but can be otherwise variously embodied and practiced within the scope of the following claims.

It will be appreciated that some components, features, and/or configurations can be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiments. Thus, the components, features, and/or configurations of the various embodiments can be combined in any manner and such combinations are expressly contemplated and disclosed by this statement.

It will be appreciated by those skilled in the art that the present invention can be embodied in other specific forms without departing from the spirit or essential characteristics thereof. The presently disclosed embodiments are therefore considered in all respects to be illustrative and not restrictive. The scope of the invention is indicated by the appended claims rather than the foregoing description and all changes that come within the meaning, range, and equivalence thereof are intended to be embraced therein. Additionally, the disclosure of a range of values is a disclosure of every numerical value within that range, including the end points.

What is claimed is:

1. A system for generating a simulated dataset related to network activity, the system comprising:
a processor; and
a memory including a data receiver module and a data synthesizer module, wherein the processor is associated with the memory and the memory includes instructions stored thereon that when executed by the processor will cause the processor to:
execute the data receiver module to receive data including time ordered data and non-time ordered data;
execute the data synthesizer module by implementing one or more machine learning models to generate synthetic data from received data, wherein:
the one or more machine learning models includes a trained dataset trained with time ordered data and non-time ordered data; and
the data synthesizer module is configured to iteratively update the synthetic data until the synthetic data meets a threshold representative of network activity.

2. The system of claim 1, wherein:
a threshold representative of network activity includes a predefined homogenous data to heterogeneous data ratio.

3. The system of claim 1, wherein:
time ordered data includes data that is at least one or more of tagged with a time stamp or encoded with a time stamp.

4. The system of claim 1, wherein:
a network activity includes at least one or more of an action, an event, or an operation within a network associated with received data.

5. The system of claim 1, wherein:
the processor executes the data receiver module to receive data from at least one or more of a live data stream of a network, a memory, a processor, or a communication system.

6. The system of claim 1, wherein:
the data synthesizer module is configured to iteratively or recursively implement the one or more machine learning models to iteratively update the synthetic data.

7. The system of claim 1, wherein:
the one or more machine learning models includes a first machine learning model and a second machine learning model;
the data synthesizer module is configured to implement the first machine learning model to iteratively update the synthetic data until the synthetic data meets a first threshold representative of a first network activity; and
the data synthesizer module is configured to implement the second machine learning model to iteratively update the synthetic data until the synthetic data meets a second threshold representative of a second network activity.

8. The system of claim 1, wherein:
instructions cause the processor to use the synthetic data as a simulated dataset to one or more of develop, train, or evaluate a machine learning model.

9. A non-transitory machine-readable medium having instructions stored thereon which when executed cause a processor to perform operations, the operations comprising:
execute a data receiver module to receive data including time ordered data and non-time ordered data;
execute a data synthesizer module by implementing one or more machine learning models to generate synthetic data from received data, wherein:
the one or more machine learning models includes a trained dataset trained with time ordered data and non-time ordered data; and
the data synthesizer module iteratively updates the synthetic data until the synthetic data meets a threshold representative of network activity.

10. The non-transitory machine-readable medium of claim 9, wherein:
a threshold representative of network activity includes a predefined homogenous data to heterogeneous data ratio.

11. The non-transitory machine-readable medium of claim 9, wherein:
time ordered data includes data that is at least one or more of tagged with a time stamp or encoded with a time stamp.

12. The non-transitory machine-readable medium of claim 9, wherein:
a network activity includes at least one or more of an action, an event, or an operation within a network associated with received data.

13. The non-transitory machine-readable medium of claim 9, wherein:
receiving data includes receiving data from at least one or more of a live data stream of a network, a memory, a processor, or a communication system.

14. The non-transitory machine-readable medium of claim 9, wherein:
the data synthesizer module iteratively or recursively implements the one or more machine learning models to iteratively update the synthetic data.

15. A method for generating a simulated dataset related to network activity, the method comprising:
executing a data receiver operation to receive data including time ordered data and non-time ordered data;
executing a data synthesizer operation by implementing one or more machine learning models to generate synthetic data from received data, wherein:
the one or more machine learning models includes a trained dataset trained with time ordered data and non-time ordered data; and
the data synthesizer operation iteratively updates the synthetic data until the synthetic data meets a threshold representative of network activity.

16. The method of claim 15, wherein:
a threshold representative of network activity includes a predefined homogenous data to heterogeneous data ratio.

17. The method of claim 15, wherein:
time ordered data includes data that is at least one or more of tagged with a time stamp or encoded with a time stamp.

18. The method of claim 15, wherein:
a network activity includes at least one or more of an action, an event, or an operation within a network associated with received data.

19. The method of claim 15, wherein:
receiving data includes receiving data from at least one or more of a live data stream of a network, a memory, a processor, or a communication system.

20. The method of claim 15, comprising:
iteratively or recursively implementing the one or more machine learning models to iteratively update the synthetic data.
